(19) United States
(12) Patent Application Publication
(10) Pub. No.: US 2008/0017869 A1
(43) Pub. Date: Jan. 24, 2008

(54) Light emitting diode chip with large heat dispensing and illuminating area

(76) Inventor: Chiu-Chung Yang, Taichung (TW)

Correspondence Address: CHARLES E. BAXLEY, ESQ., 90 JOHN STREET, THIRD FLOOR, NEW YORK, NY, 10038, US

(21) Appl. No.: 11/903,936

(22) Filed: Sep. 24, 2007

Related U.S. Application Data
(63) Continuation-in-part of application No. 11/285,799, filed on Nov. 23, 2005, now abandoned.

(51) Int. Cl. H01L 33/00

(52) U.S. Cl. 257/79; 257/E33.001

(57) ABSTRACT

A light emitting diode chip has a large area of electricity conducting layer applied to each of the P pole and the N pole. The etching process does not reduce the illuminating area so that the areas of illumination and reflection are increased and the efficiency for dispensing heat is increased. The light emitting diode chip needs no encapsulation and includes functions as those flip chips and SMD.

### FIELD OF THE INVENTION

This application is a Continuation-In-Part application of applicant's former patent application Ser. No. 11/285,799, filed on Nov. 23, 2005.

### BACKGROUND OF THE INVENTION

A conventional light emitting diode chip is shown in FIG. 1 and generally includes the N pole 1 and the P pole 2 with a gap 3 defined therebetween. An etching process is applied to form the N pole which reduces the illuminating layer 4 of the chip so that the illumination is weakened which cannot meet requirement in the market.

FIG. 2 shows a welding technique named SMD to the light emitting diode chip wherein the chip 5 has to reserve the wiring position on the N pole 6 and the P pole 7 so that the chip 5 can be connected to the package substrate 22 by the wires 8 and the package substrate 22 is then electrically connected to the printed circuit board 60.

FIG. 3 shows a welding technique named flip-chip to the light emitting diode chip wherein the chip 5 have to mount on package substrate 23, so that metal beads 9 have to be welded to the package substrate 23 by welding process. The chip 5 is then welded to the package substrate 23 which is welded to the printed circuit board 60 by conventional tin paste.

The present invention intends to provide a light emitting diode chip and the present invention needs no submount process when compared with the convention flip-chip packaging. When compared with the convention SMD packaging, the present invention needs no wire bonding and mounting the chip on the package substrate.

### SUMMARY OF THE INVENTION

The present invention provides a light emitting diode chip and a large area of electricity conducting lay is setup on each of the P pole and the N pole so that the area of illumination is increased and the efficiency for dispensing heat is increased. The light emitting diode chip needs no encapsulation and the packaging process of flip-chip and SMD and the chip has functions as those flip chips and SMD.

The present invention will become more obvious from the following description when taken in connection with the accompanying drawings which show, for purposes of illustration only, a preferred embodiment in accordance with the present invention.

### BRIEF DESCRIPTION OF THE DRAWINGS

FIG. 1 is a cross sectional view of a conventional chip;

FIG. 2 shows a welding technique named SMD to the light emitting diode chip;

FIG. 3 shows a welding technique named flip-chip to the light emitting diode chip;

FIG. 4 is a cross sectional view to show the chip of the present invention, and

FIG. 5 shows that the chip of the present invention is welded to a printed circuit board.

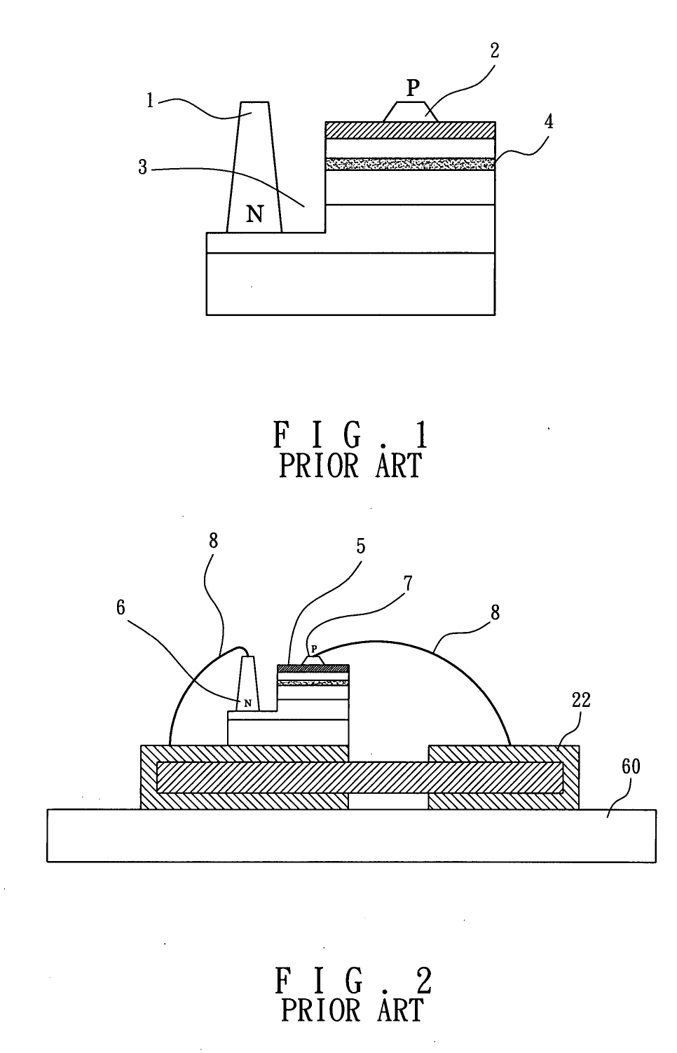

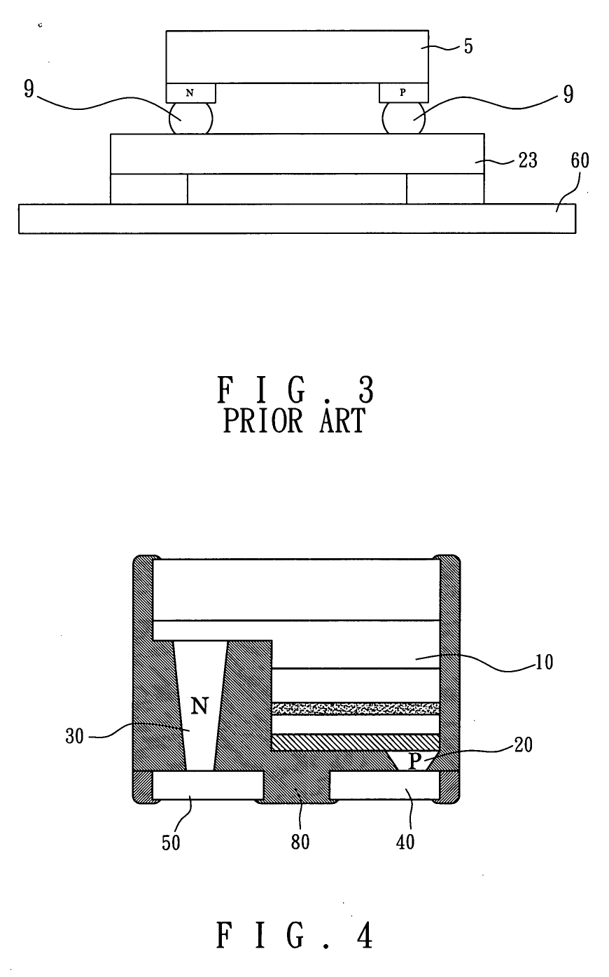

### DETAILED DESCRIPTION OF THE PREFERRED EMBODIMENT

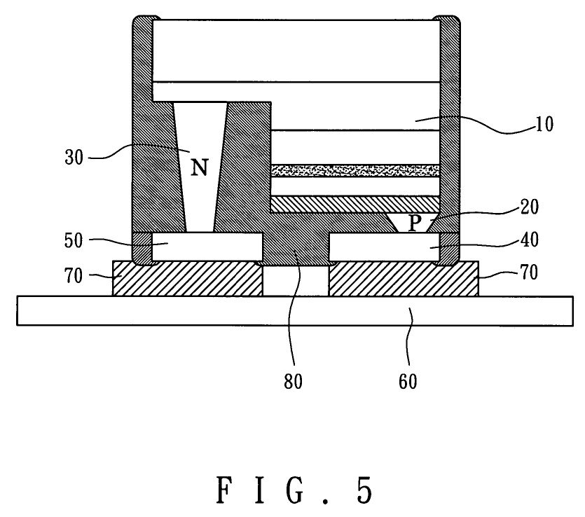

Referring to FIG. 4, the light emitting diode chip 10 has the P pole 20 and the N pole 30 on one side thereof and the N pole 30 and the P pole 20 are formed by die process. Two large areas of electricity conductive layer 40 and 50 are setup on the P pole 20 and the N pole 30 respectively and the large areas of electricity conductive layer 40 and 50 must larger than two respective end surfaces of the P pole 20 and the N pole 30. Each of the electricity conductive layers 40, 50 is made by gold, silver, copper, aluminum, tin or alloy. By the large areas of the of electricity conductive layer 40 and 50, the chip 10 has a large area for dispensing heat and for reflecting light and for electricity conductive function. The chip 10 of the present invention needs no package process so that the manufacture cost can be reduced.

The chip 10 is made with multiple layers and a protection layer is coated thereon. An evaporation system is used to form the large area of electricity conductive layer 40. The large areas of electricity conductive layer 40 and 50 are setup on the P pole 20 and the N pole 30 respectively. When the chip 10 is welded to the printed circuit board 60, as show in FIG. 5, the electricity conductive layer 40 and 50 is welded by conventional tin paste 70. The welding processes are simple and can be completed within a short period of time.

Because of the large areas of electricity conductive layer 40, 50 being setup on the P pole 20 and the N pole 30 so that the chip 10 needs no package substrate and can be directly connected to the printed circuit board 60 by conventional welding methods. The chip 10 has all the functions that SMD and flip chips without package. The large area of the electricity conductive layers 40, 50 have good efficiency of dispensing heat and reflect light so that the chip 10 have good illumination feature. The electricity conductive layers 40, 50 can be easily welded to the printed circuit board 60.

While we have shown and described the embodiment in accordance with the present invention, it should be clear to those skilled in the art that further embodiments may be made without departing from the scope of the present invention.

What is claimed is:

1. A chip comprising:
a P pole and a N pole, each of the P pole and the N pole having a large area of electricity conductive layer setup thereon, the large area of electricity conductive layers being larger than two respective end areas of the N pole and the P pole, the electricity conductive layers reflecting light, the chip having function of SMD and flip-chip without encapsulation.

2. The chip as claimed in claim 1, wherein each of the electricity conductive layers is made by gold, silver, copper, aluminum, tin or alloy.
